(19) United States
(12) Patent Application Publication
(10) Pub. No.: US 2009/0155963 A1
(43) Pub. Date: Jun. 18, 2009

(54) FORMING THIN FILM TRANSISTORS USING ABLATIVE FILMS

(76) Inventors: Gilbert A. Hawkins, Mendon, NY (US); Peter A. Stolt, Edina, MN (US); M. Zaki Ali, Mendota Heights, MN (US)

Correspondence Address: Frank Pincelli;Patent Legal Staff, Eastman Kodak Company, 343 State Street, Rochester, NY, 14650-2201, US

(21) Appl. No.: 11/954,307

(22) Filed: Dec. 12, 2007

(51) Int. Cl. H01L 21/336; G03C 1/00

(52) U.S. Cl. 438/151; 430/270.1; 257/E21.411

(57) ABSTRACT

An ablative film arranged in a stack having a flexible substrate disposed in the stack; an active layer, disposed in the stack, including at least a semiconductor material; and at least one ablative layer, disposed in the stack over the active layer, that is removable by image wise exposure to radiation from the top side of the stack.

### FIELD OF THE INVENTION

This invention relates generally to the field of thin film transistor fabrication, including fabrication of thin film transistors on flexible substrates, and particularly to low temperature means for inexpensively forming high quality, interconnected transistors on polymer substrates using a very small number of processing steps. More specifically, the invention discloses processes providing thin film transistors using laser ablatable films.

### BACKGROUND OF THE INVENTION

Conventional silicon transistor technology, such as that practiced in the fabrication of Very Large Scale Integrated (VLSI) circuits, is unchallenged for device performance in applications such as computer processors. However, the cost per unit area of VLSI processing is high and the size of the monolithically integrated devices is limited to a fraction of the size of the largest silicon wafer technology, which today is 300 mm. For some applications, for example flat panel displays, the sizes of the substrates (greater than 1 meter diagonal) are incompatible with the size restrictions of VLSI and the cost requirements are incompatible with VLSI processing costs. For these large areas, low cost applications, thin film amorphous and microcrystalline transistor technology on glass panels is the current technology of choice for the backplane electronics. Other thin film transistor applications include devices made on flexible substrates, such as plastics and metal foils, etc. All these applications use processing steps that are lower in temperature than those used in integrated circuit technology, since the substrates generally cannot withstand the high temperatures used in conventional silicon technology. For example, they cannot withstand temperatures of 900 to 1000 degrees C. typically used for growth of oxides and implant anneals in single crystal silicon technology. For these applications, transistors based on amorphous silicon, microcrystalline silicon, and organic materials have been developed which can be processed at relatively low temperatures. Their performance is adequate for today's flat panel displays, but none exhibit the speed, insensitivity to environmental conditions, and other high performance characteristics of conventional silicon processed at high temperatures.

While some developments have been made in thin film transistor technologies for devices that can be processed at relatively low temperatures, for example laser annealed silicon films or low temperature annealed polycrystalline silicon films on glass, the aggregate of processing steps for such thin film technologies required to provide integrated transistor arrays is still very large, and yields and cost have suffered. Co-pending application, Ser. No. 11/737,187 filed Apr. 19, 2007, discloses interconnection of microsized devices by wicking of conductive fluids to form low cost, high performance circuits on low-temperature substrates. Transistor circuits on such microsized devices are typically formed on conventional silicon wafers with conventional silicon processing and must be therefore be made prior to the process of microsized device interconnection and positioned individually on the substrate prior to microsized device interconnection. Other processes, for example those disclosed in U.S. Pat. No. 7,253,087 by Utsunomiya, assigned to Seiko Epson Corporation, similarly use fluid conductive materials to connect circuits formed by placing conventional VLSI chips on flexible substrates. However, these fabrication processes require making chips by conventional methods, which typically takes several weeks of processing time, and then placing them with sufficient accuracy to allow interconnection. Also, these processes do not allow rapid alteration of basic chip functionality at the time the chips are interconnected. For future applications, it would clearly be desirable to directly fabricate thin film transistors on the low temperature substrates while retaining the performance, speed, and stability of conventional silicon devices. Preferably, such transistors would be fabricated in arbitrary configurations during the same processing sequence as the interconnects themselves.

Many additional processes for forming transistors and other active components on flexible substrates have been disclosed meeting some, but not all, of the desired features for fabrication. Some rely on patterning, depositing, and etching technologies similar to those employed in the silicon Very Large Scale Integration (VLSI) industry, but adapted to flexible substrates, as described in U.S. Pat. No. 7,223,672 by Kazlas et al and assigned to E Ink Corporation. However, this approach requires substantial equipment and processing cost. Wolk et al., U.S. Pat. No. 6,586,153 discloses the use of light-to-heat-conversion layers that can be used to transfer multicomponent transistor into a receptor (substrate). However, transfer technologies necessarily involve more than single layer processing. In all cases, care is taken to provide low temperature processing so that substrate damage is minimized. For example, in U.S. Pat. No. 7,112,846 by Wolfe et al., substrates coated with films whose optical properties allow substantial laser exposure to components benefiting from this processing are juxtaposed in particular regions with films, including the substrate, which suffer from excessive exposure. However, the constraints on device design imposed by such requirements are complex and lateral degradation of device performance is unavoidable.

Other processes have been disclosed to reduce the cost of conventional processing by reducing the complexity of selected groups of process steps such as lithography. For example, Baude et al., U.S. Pat. No. 7,297,361, discloses the use of web-based, thin film shadow masks through which various materials may be deposited before the mask is peeled away and discarded. Theiss et al, describes shadow masking to avoid certain lithographic patterning steps entirely. Tredwell et al., U.S. Pat. No. 7,198,879 describe a process for directly transferring masking material from a donor sheet to the substrate desired to be patterned that replaces the conventional steps of coating, exposing, and developing photo resist using laser radiation of the donor. Advantageously, this method allows the mask pattern to be made digitally at the time of fabrication rather than relying on the time consuming step of mask making, as in conventional VLSI processing. To similar advantage, Quick et al, U.S. Pat. No. 7,268,063 discloses localized deposition of various active and passive materials by laser-chemical interactions. Still, all these process require a substantial number of process steps of various kinds, each using different fabrication tools.

To further reduce costs and to allow in-situ fabrication of all active circuit elements at the time of manufacture of the flexible substrates, novel liquid deposition processes such as inkjet have been proposed for depositing and patterning metals, dielectric insulators, and even active materials from solutions or solution precursors, as disclosed in, for example, U.S. Pat. No. 7,277,770 by Huang, U.S. Pat. No. 6,927,108 by Weng et al, U.S. Pat. No. 7,138,170 by Bourdelais et al, and U.S. Pat. No. 7,037,767 by Hirai. In particular, U.S. Pat. No. 7,214,617 by Hirai, assigned to Seiko Epson Corporation, describes detailed methods for precisely patterning functional liquids between polymer banks formed by conventional etching processes including modifying the functional liquid contact angle on various surfaces using repellency layers and baking the deposited functional liquid to form conductive materials. Materials so formed may not be limited to conductive materials: for example, Kovio, Inc., has described their intent to commercialize the use of silicon nanoparticles dispersed in liquids as precursor materials for active semiconductor layers. In principal, ink jetting of active and passive components in a single, web-based process from precursor fluids offers advantages of productivity, cost, process simplicity and the ability to digitally design-on-demand both active components and their interconnections.

To still further reduce costs and allow in-situ fabrication of all active circuit elements at the time of manufacture of flexible substrates, lamination transfer technologies have been disclosed, for example US 2007/0020821 by Toyoda and assigned to Seiko Epson, Incorporated, describes several sequential transfers of material layers, both active and passive, from one or more donor substrates to a flexible substrate on which the final devices and circuits are formed. Although the layer structures involved in the intermediate processes in some cases resemble the structures disclosed in some of the embodiments of the present invention, the processing sequence of lamination transfer disclosed in US 2007/0020821, which occurs under vacuum, is not contemplated or taught in the present invention, and the substrate requirements for the lamination transfer disclosed in US 2007/0020821 require the transfer substrate to be substantially transparent to the radiation initiating such transfer. Additionally, the order of the layers required for thermally activated transfer place a single ablative layer or “thermal release” layer between the substrate and the layer to be transferred, for example an active layer or a metal layer. In this configuration, radiation from the topside of the substrate would, for example, reflect off a metal layer with out contacting the “release” layer. If such radiation from the topside encountered an active material transparent to the radiation, then the release layer would act on the active material from only one side, presumably releasing or ejecting it into the incident radiation beam. Such transfer layers are not taught to be processed by radiation incident from the top side (side opposite the substrate.)

### SUMMARY OF THE INVENTION

In copending application, Ser. No. 11/737,187 filed Apr. 19, 2007, a process is disclosed for using ablative films to achieve interconnections between micro-sized devices of a variety of types. For the case of electrical interconnections, this process involves forming deliberately located channels in which are deposited conductive inks that wick into contact portions of the micro-sized devices to ensure the reliable connection of electric leads to the devices or “die.” The present invention supplements this process by providing means for forming simultaneously active circuit elements having the functionality of the micro-sized devices of copending application, Ser. No. 11/737,187, without the necessity of making the micro-sized devices independently; that is, the active circuit elements are formed in processes similar to and simultaneously applied with those required in forming interconnections in copending application, Ser. No. 11/737,187.

In accordance with the present invention, low cost, thin film transistors and circuits are formed by simple processes on substrates that cannot be subjected to high temperatures. Yet these transistors and circuits may have the performance, speed, and stability of conventional silicon devices. Specifically, the present invention envisions a process of forming thin film transistors comprising: providing an ablative film having a substrate with at least one ablative layer and a layer of active material; forming channels in said ablative layer by exposure of the ablative film to radiation, the channels extending to the layer of active material; and providing at least one conductive material in the said channels to form multiple electrical connections to the active material.

These and other aspects, objects, features and advantages of the present invention will be more clearly understood and appreciated from a review of the following detailed description of the preferred embodiments and appended claims, and by reference to the accompanying drawings.

### ADVANTAGEOUS EFFECT OF THE INVENTION

Advantageously, the circuits provided by the present invention are produced at low cost and with few process steps.

Also advantageously, the circuits so formed are produced at very low processing temperatures.

A feature of the present invention is that the low-cost circuits so formed are of a performance type nearly equal or exceeding the performance of high-temperature silicon circuits employed by the computer chip industry.

Another feature is that active materials are provided within the ablative film prior to processing the ablative film to form particular types of circuits or circuit elements such as transistors and that the ablative films may be packaged and stored before such processing.

These and other aspects, objects, features and advantages of the present invention will be more clearly understood and appreciated from a review of the following detailed description of the preferred embodiments and appended claims, and by reference to the accompanying drawings.

### BRIEF DESCRIPTION OF THE DRAWINGS

FIG. 1a is a cross-section of a prior art ablative film having two energy absorbing layers on a substrate that does not appreciably absorb radiation;

FIG. 1b is a cross-section of a prior art ablative film having four layers on a substrate, some of which are energy absorbing layers;

FIGS. 2a and 2b illustrate in cross-section and top-view, respectively, prior art formation of a channel in an ablative film having two energy absorbing layers on a substrate;

FIG. 2c illustrates in cross-section a prior art process for forming an electrically conductive material in an ablated channel in an ablative film 5 having two energy-absorbing layers;

FIG. 3 illustrates in cross-section a prior art process for forming a circuit including an electrical connection to an active element containing transistors;

FIG. 4a illustrates the ablative film 125 in accordance with the present invention having an ablative layer. The inset shows in cross-section an active material surrounded by an insulator which comprises all or part of the active layer.

FIG. 4b is a cross section of FIG. 4a illustrating ablated channels;

FIG. 4c is a cross section of FIG. 4b illustrating the conductive materials in the ablated channels;

FIG. 4d is a top view of FIG. 4b illustrating the ablated channels;

FIG. 4e is a top view of FIG. 4c illustrating the conductive materials;

FIG. 4f is a top view of FIG. 4c illustrating the conductive materials and the plurality of active layers;

FIGS. 4g-4l are cross sections similar to those of FIG. 4a-4c illustrating the formation of a related transistor in accordance with another embodiment of the present invention.

FIG. 5a illustrates in cross-section an alternative embodiment of the ablative film having a single, ablative layer, a semiconductor active material layer, and a substrate;

FIG. 5b illustrates in cross-section the ablative film of FIG. 5a after formation by laser radiation of a single ablated channel;

FIG. 5c illustrates in cross-section the ablative film of FIG. 5b after conductive materials of a first type have been deposited on the right and left portions of the single ablated channel;

FIG. 5d illustrates in cross-section the ablative film of FIG. 5b after the single ablated channel (single ablated region) has been filled with a conductive material of a first type and of a second type;

FIG. 6a illustrates in cross-section an ablative film having two ablative layers, a semiconductor active material layer, and a substrate 160 which layers are to be subjected to an alternative process;

FIG. 6b illustrates in cross-section the ablative film of FIG. 6a after formation, by laser radiation, of three ablated channel regions;

FIG. 6c illustrates in cross-section the ablative film of FIG. 6b after the ablated channels have all been filled with a conductive material;

FIG. 7a illustrates in cross-section another alternative embodiment of the ablative film having two ablative layers;

FIG. 7b illustrates in cross-section the ablative film of FIG. 7a after formation, by laser radiation, of a single ablated channel;

FIG. 7c illustrates in cross-section the ablative film of FIG. 7b after the ablated channel has been filled with a conductive material;

FIG. 7d illustrates in cross-section the ablative film of FIG. 7c after two additional ablated channels have been formed;

FIG. 7e illustrates in cross-section the ablative film of FIG. 7b after the additional ablated channels have been filled with a conductive material;

FIGS. 7f-7i illustrate an alternative process similar to the process described in association with FIGS. 7a-7e, except that the order of providing the central ablative channel and the additional ablative channels is reversed;

FIGS. 8a and 8b illustrate the initial steps of a process for providing transistors that begin identically to that illustrated in FIGS. 7a and 7b;

FIG. 8c illustrates the step of deposition of conductive materials, analogous to that illustrated in FIG. 7c, except the ablated central channel extends laterally to the conductive materials on both sides;

FIG. 8d shows selective deposition of an insulator material on the conductive materials, for example by vapor exposure to materials that adhere only to metals;

FIG. 8e illustrates in cross-section the device of FIG. 8d after the central ablated channel has been filled with a conductive material to form the transistor gate; and

FIG. 9 shows a schematic top view of circuitry created by the embodiments described above.

### DETAILED DESCRIPTION OF THE INVENTION

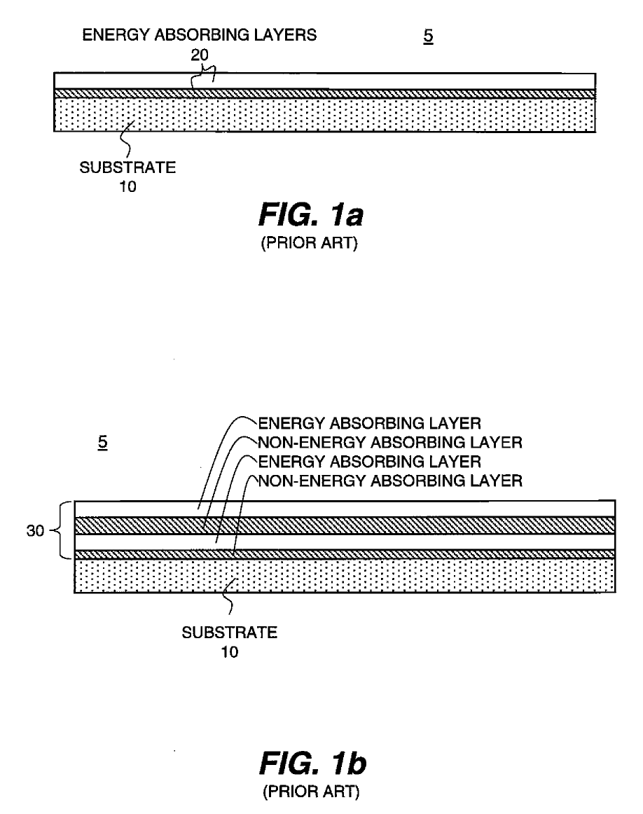

FIG. 1a is a cross-section of a prior art ablative film 5 having two 2 0 energy absorbing layers 20 on a substrate 1 0 that does not appreciably absorb radiation. There are no active material layers, that is, there are no layers containing semi-conductive materials, in this ablative film. During exposure to laser radiation, one or both energy absorbing layers 20 may be entirely or partially ablated away over portions of the substrate.

FIG. 1b is a cross-section of a prior art ablative film 5 having four layers 30 on a substrate 10, some of which are energy absorbing layers 20. There are no active material layers in this ablative film. During exposure to laser radiation, energy absorbing and non-energy absorbing layers in layers 30 may be entirely or partially ablated away over portions of the substrate. Generally, non-energy absorbing layers in layers 30 lying over energy absorbing layers in layers 30 are entirely ablated when one or more of the underlying layers is ablated.

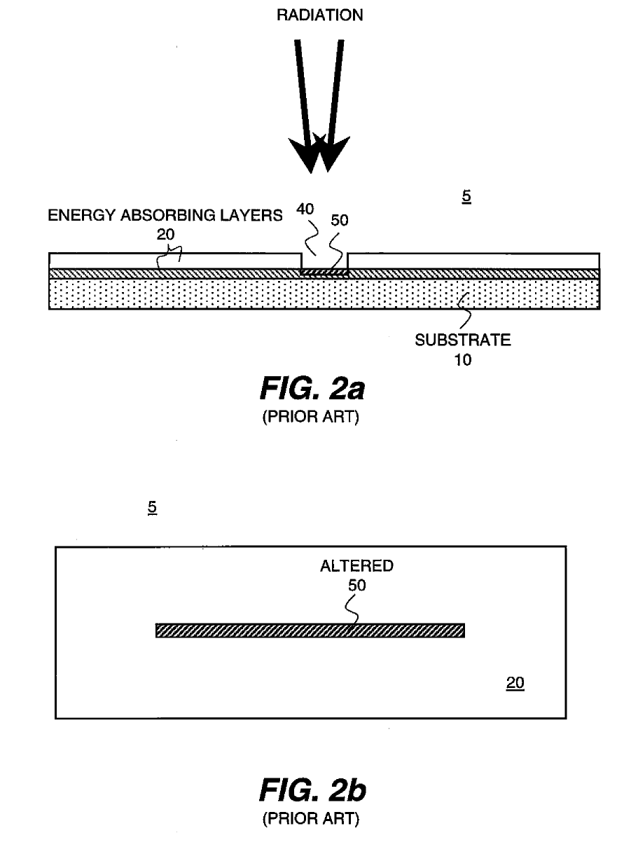

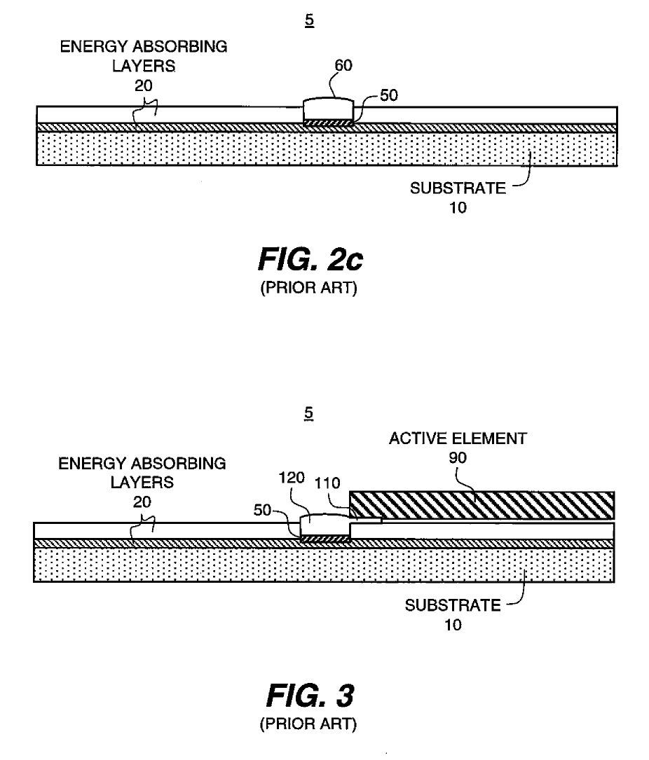

FIGS. 2a and 2b illustrate in cross-section and top-view, respectively, prior art formation of a channel 40 in an ablative film having two energy absorbing layers 20 on a substrate 10. There are no active material layers in this ablative film. The lower absorbing layer of absorbing layers 20 in the region of formation of channel 40 is not entirely ablated away but has been altered through a portion of its thickness to become altered absorbing layer 50, the alteration being one of composition or thickness caused by the formation of channel 40.

FIG. 2c illustrates in cross-section a prior art process for forming an electrically conductive material 60 in an ablated channel in an ablative film 5 having two energy-absorbing layers 20. The lower absorbing layer of absorbing layers 20 in the region of formation of channel 40 is not entirely ablated away but has been altered partially through its thickness to become partially altered absorbing layer 50, the partial alteration being one of composition or thickness caused by the formation of channel 40.

FIG. 3 illustrates in cross-section a prior art process for forming a circuit including an electrical connection 1 10 to an active element 90 containing transistors. Connecting material 120 wets the surface of partially altered absorbing layer 50 of FIG. 2c, as described in co-pending application, Ser. No. 11/737,187 filed Apr. 19, 2007.

Before describing the present invention, it is beneficial to define terms as used herein. In this regard, an active layer as used herein means a layer comprised all or in part of a semiconductive layer or of one or more semiconductor portions. The semiconductor layer or semiconductor portions may be surrounded partially or totally by a dielectric insulator unless specifically defined differently. It is also to be understood that portions of the semiconductor layer or of the one or more semiconductor portions may be doped, using either n-type or p-type doping, so that transistors may be formed, as is well known in the art of semiconductor fabrication. In the case that the active layer comprises one or more semiconductor portions, the portions may entirely comprise the active layer or remaining portions of the active layer may include a polymer binder in which the one or more semiconductor portions are dispersed. The one or more semiconductor portions may be distributed uniformly spatially in the active layer or may be patterned laterally so as to occupy only selected portions of the active layer.

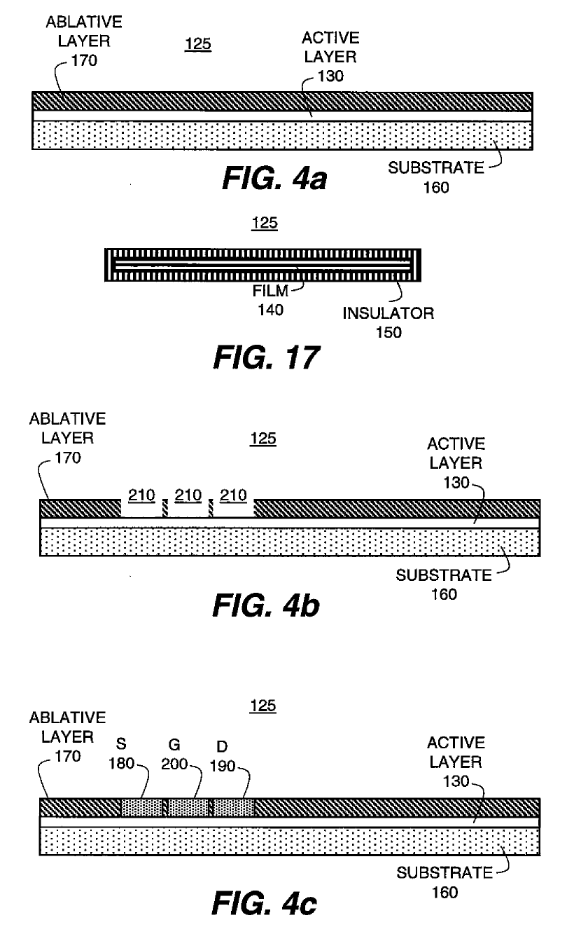

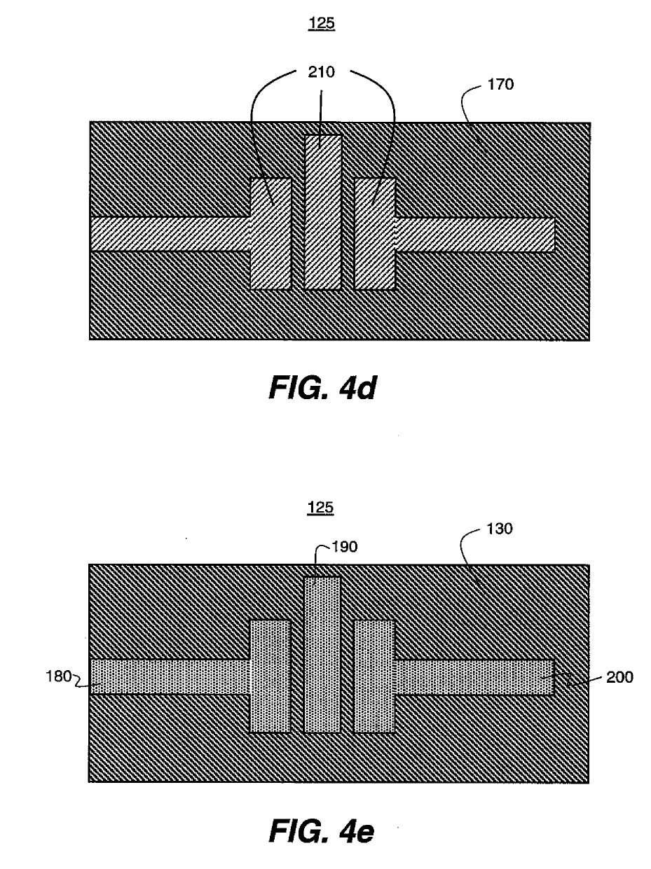

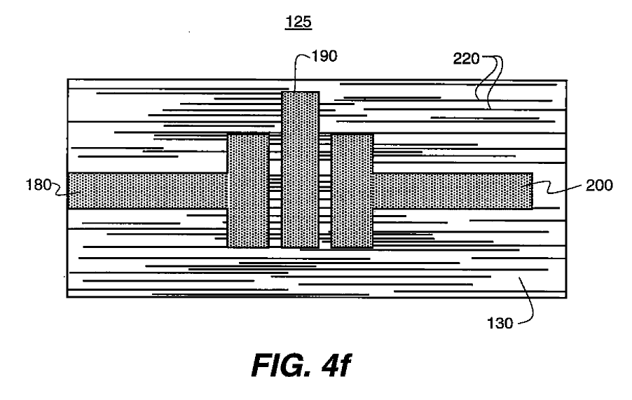

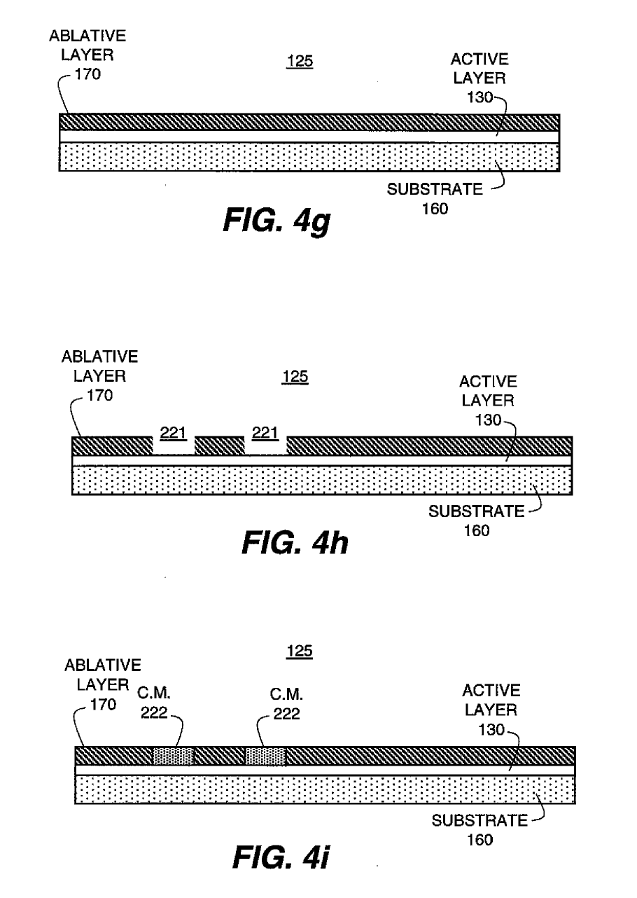

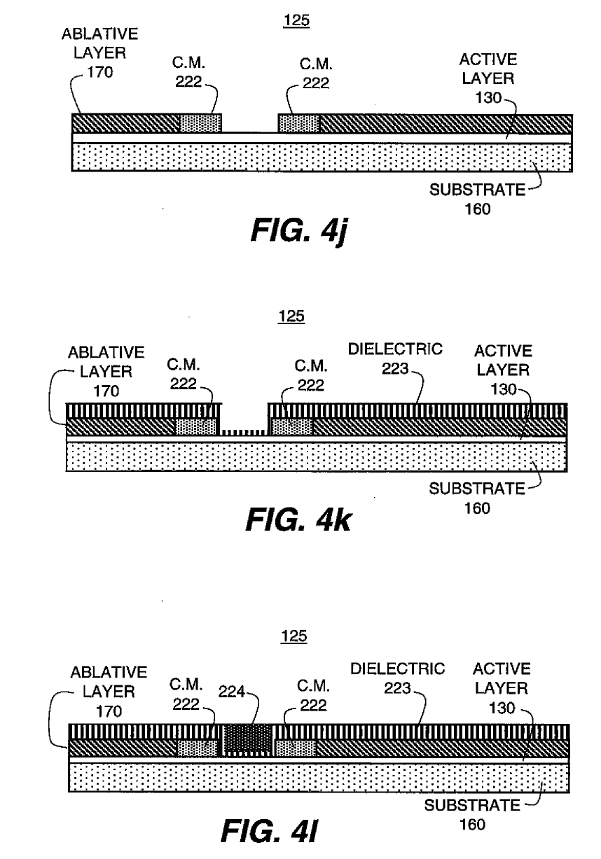

Referring to FIG. 4a, the ablative film 125 in accordance with the present invention includes an active layer 130, which is described herein as a layer containing an active material 140 capable of providing the functionality of a solid-state transistor device when properly processed and electrically connected, such as a semiconductor material. The active material may be, for example, a thin film of an inorganic semiconductor material such as silicon, germanium, GaAs, ZnO, etc, or combinations of these films; or thin films of organic semiconductor materials, such as pentacene, or the active material may be comprised of discreet pieces or segments of such semiconductors of various sizes or shapes, such as carbon, silicon, or germanium nanotubes in the form of cylinders or wires or graphene flakes in the form of two-dimensional segments which are semiconducting. In the case that the active material 140 has the form of a uniformly deposited, thin semiconducting film, and, referring briefly to FIG. 17, the active material is preferably surrounded by an insulator 150 on the top or on both the top and bottom which acts as all or part of a gate dielectric, as is also well known in the art of thin film electronics. In this case, the active layer is essentially a uniformly deposited, thin semiconductor film having a uniformly deposited dielectric insulator above and/or below it. In the case that the active material 140 is in the form of two-dimensional segments or flakes of a thin semiconducting film, and again referring to FIG. 17, the flakes of the active material are preferably surrounded by a dielectric insulator 150, which acts as all or part of a gate dielectric. In this case the flakes of active material and their surrounding insulator may be the only constituents of the active layer or such flakes and surrounding dielectrics may be embedded in a binder, such a polyamide polymer binder. In the case that the active material 140 is in the form of one-dimensional cylindrical rods or wires of a semiconducting material, the semiconducting rods or wires are preferably surrounded by a dielectric insulator which acts as all or part of a gate dielectric. In this case the rods or wires of active material and their surrounding dielectric insulators may be the only constituents of the active layer or such wires and surrounding dielectrics may be embedded in a binder. Unless otherwise stated, the active layers 130 disclosed in the present invention comprise active materials and any associated insulators; in other words, an active material of any type may include a dielectric insulator on its surfaces. Specifically, in the case the active layer is includes segments of semiconductors of various sizes or shapes, for example nano-wires, nano-tubes, or two-dimensional flakes, the semiconductor material segments may be surrounded partially or entirely by a dielectric insulator which may act as all or part of a gate dielectric, as is well known in the art of thin film electronics. Films formed from nanowires of silicon, carbon, germanium etc. or films formed from thin flakes of semiconducting materials, including organic materials and metal oxides, are well know in the art of thin film electronics. For example, U.S. Pat. No. 7,105,428 by Pan et al., and U.S. Pat. No. 6,996,147 by Majumdar et al. describe the growth and harvesting of silicon nanowires. However, commercialization of these active layers has heretofore been difficult due to cost and complexity of reliable and reproducible means of processing such active layers.

In some embodiments, in which the active materials comprise cylindrical segments, the cylinders are less than 0.1 microns in diameter, greater than 5 microns in length, and substantially angularly aligned on the substrate. Preferably, the density of such segments is sufficiently small so that no conductive paths are formed over distances greater than 10 times their largest dimension of the cylindrical segments because they rarely overlap one another, thereby preventing accidental conductive paths.

The ablative film 125 in FIG. 4a is comprised of three layers: substrate 160, active layer 130 and ablative layer 170. In accordance with the present invention, the substrate is preferably flexible, so that the resulting transistor circuits are flexible and thereby useable in applications facilitated by flexible manufacturing techniques or in applications requiring product flexibility, for example in flexible electronic displays. However, the substrate contemplated in the present invention may also be a rigid substrate, for applications such as radiography in which the product need conform to geometrical constraints.

The ablative film 125 is processed (FIG. 4b-e) to provide transistors having electrical connections, including connections to other transistors so formed. The connections to the transistors are typically labeled source, drain, and gate connections, the source and drain connections forming ohmic contacts to the active material of the active layer, while the gate connection is capacitively coupled to the active material of the active layer, as is well known to those skilled in semiconductor device technology. For the case that the active layer 130 is surrounded on some or all sides with a gate insulator (or gate dielectric), the source and drain electrical connections require removal or degradation to a current transportive state of the insulator to achieve electrical contact, preferably ohmic contact, as is well known in the art of electronic devices. Removal of insulators may be achieved by dry or wet chemical treatments or by sputter etching, for example.

Before discussing the present invention further, the following characteristics are noted. The substrate 160 may be either rigid or flexible and may be either substantially transparent or optically absorptive. The ablative layer 170 preferably absorbs radiation in the range of 800-1200 nm, including having an absorption coefficient greater than or equal to 200,000 m-1. These ranges are especially appropriate for manufacturing using readily available tools, for example laser writers having infrared beam arrays capable of exposing large area ablative films. Such writers preferably absorb at least 10% of their energy in the layers ablated, in order to pattern large area arrays efficiently. Also, the ratio of absorption coefficients of the ablative layer and active layer is preferably greater than 5, in order that the active layer does not overheat due to direct radiation absorption during ablation of the ablative layer. The lateral dimensions of the ablative film 125 contemplated in the present invention preferably may preferably exceed 100 cm in one direction in order that many devices may be fabricated simultaneously. Such large area materials, herein ablative films, are preferably fabricated by mass production methods to reduce costs and are stored prior to processing so as to facilitate product workflow.

FIGS. 4a-4c illustrate in cross-section an ablative film 125 in accordance with the present invention comprising a single ablative layer 170, a single active layer 130, and a substrate 160 to be subjected to a first process for forming a transistor having a source region 180, a drain region 190, and a gate region 200, which regions will be electrically connected by the processes described herein. It is noted in FIG. 4b that three channels 210 are created in the ablative layer 170 into which conductive materials, which are electrical conductors, will be provided to form electrical connections to the transistor source region 180, drain region 190, and gate region 200, respectively. Referring briefly to FIG. 17, in this example, the active layer 130 comprises a thin film of uniformly deposited active material 140 surrounded on all sides by an insulator that acts as a gate dielectric. In other words, the active layer in FIG. 4a-c includes a uniform semiconductor film and the film is envisioned to include an insulator at least on its top surface, such as silicon or aluminum oxide, which acts as all or part of a gate dielectric. In the alternative case in which the active layer 130 includes an active material comprising segments of semiconductors, such as semiconductive nanowires, the segments, for example the nanowires, are envisioned to be surrounded by a dielectric insulator which acts as all or part of a gate dielectric. Such gate dielectric layers are well known to be provided by thermal oxidation in the case the active materials are silicon or by thin film physical or chemical vapor deposition of an insulator for materials which do not readily grow thermal oxides.

FIG. 4b illustrates in cross-section the ablative film 125 of FIG. 4a after formation, by exposure to radiation, for example laser radiation, of channels (ablated regions) 210 extending down to the semiconductor active layer 130.

FIG. 4c illustrates in cross-section the ablative film 125 of FIG. 4b after the channels (ablated regions) 210 extending down to the semiconductor active material layer 130 have been filled with conductive materials in the source region 180, drain region 190, and gate region 200, respectively. The conductive materials in the example of FIG. 4c have been provided by first depositing fluid conductive materials, for example by inkjet printing, of two different fluid conductive material types. The first type of fluid conductive material, the source and drain fluid conductive materials, respectively, are designed so as to provide direct electrical (preferably ohmic) contact to the active material. The gate fluid conductive material is designed so as to provide capacitive contact to the active material. In this embodiment, deposition of the fluid conductive materials is followed by drying and/or annealing, for example for one hour at 200 C, to form conductive materials, which are electrical conductors, as is well known in the art of inkjet printing of conductive materials comprised of copper or silver nanoparticulates. Since in this example the active layer 130 includes an insulator on the surface of the active material in the active layer, the source-drain fluid conductive materials, respectively, preferably contain chemical additives such as hydroxyl ions or acid enchants, such as hydrofluoric acid, that compromise the integrity of the dielectric insulator surrounding the active material upon deposition of the source-drain fluid conductive materials or during annealing of same to allow holmic contact of the subsequently formed conductive materials to the active material. On the other hand, gate fluid conductive material preferably contains no chemical additive that dissolve or etch away the insulator layer surrounding the active material in the gate region 200, in order to ensure capacitive contact to the active material in the gate region, as is well known in the art of transistor fabrication.

Following deposition of the two fluid conductive material types, the two fluid types are dried and/or annealed to form conductive materials located in source-drain regions 180 and 190 and gate region 200. These conductive materials provide source, drain, and gate connections for the transistors so formed, as can be appreciated by one skilled in semiconductor device fabrication. Generally, conductive materials are formed by first depositing fluid conductive materials, for example by inkjet deposition, followed by annealing and/or drying of the fluid conductive materials.

FIG. 4d illustrates a top view of a transistor formed in accordance with the process of FIG. 4b after formation by laser radiation of channels 210 (ablated regions) extending down to the active material layer 130 (black) to form a transistor having source 180, drain 190, and gate 200 regions (FIG. 4c).

FIG. 4e illustrates a top view of FIG. 4d after formation of source-drain conductive material filled regions and gate conductive material filled regions, thereby providing source-drain-gate electrical connections. In FIG. 4e, the ablative layer 170 is hidden, revealing the active layer 130 (black). In FIG. 4e, the active layer 130 is shown as including a uniformly deposited semiconductive film.

FIG. 4f illustrates a top view of FIG. 4d after formation of source-drain conductive material filled regions (source-drain filled regions) and gate filled regions, both in appropriate electrical contact to the active material 130, thereby providing source-drain-gate electrical connections. In FIG. 4f, the ablative layer 170 is hidden, revealing the active layer 130. In FIG. 4f, the active material 130 is shown comprised of conductive segments 220, such as silicon rods or nanowires, with the segments individually isolated from one another and aligned in the source to drain direction (horizontal lines in FIG. 4f). Such alignment is advantageous in providing a high probability that an individual wire bridges the region between the source and drain, as can be appreciated by one skilled in the art of thin film semiconductor fabrication. The fact that the nanowires are substantially isolated one from another ensures that no electrical connections are likely formed, for example between the source and drain, via paths remote from the source drain regions. There is thus preferably no electrical path between the conductive materials 220, except for those segments 220 which each span the distance between the source and the drain filled regions. This property can be ensured because the density of the segments is so low that the chance of segments overlapping one another is small over distances greater than about ten times the length of the segments, as can be appreciated by one skilled in thin film electronics.

FIGS. 4g-4l show a method for creating a transistor related to the method of FIG. 4c. FIG. 4g shows a substrate 160 having one active layer 130, which in FIG. 4h is shown to be ablated at two locations 221, thereby creating two recess portions in the ablative layer 170 extending to active layer 130. FIG. 4i shows a first electrical conductive material 222 deposited in each of the two recess portions 221 forming source drain ohmic contacts to the active material; and FIG. 4j shows removal, by ablative radiation, for example laser radiation, of the ablative layer 170 between the two contacts 222. FIG. 4k shows the transistor after deposition of a dielectric material 223, such as silicon dioxide or a polymer, and FIG. 4l shows subsequent deposition of a second conductive material 224, forming a gate contact to the active material.

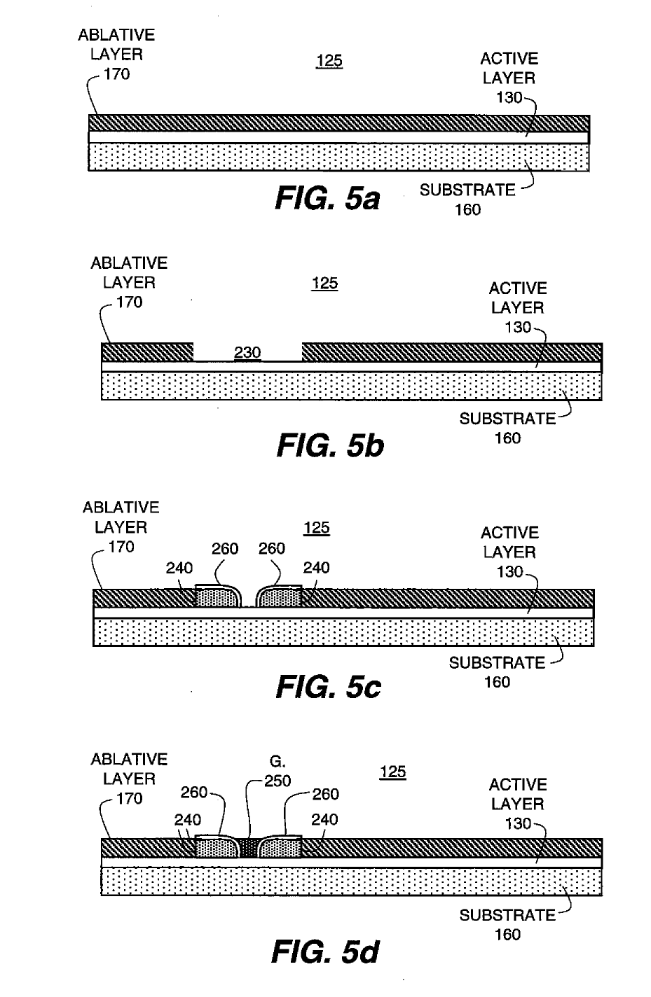

The process shown in FIGS. 5a-5d differs from the process of FIG. 4a-4e in that only a single, contiguous channel (ablative region) 230 is formed rather than three, spaced-apart ablative channels. Following formation of the single channel, two spatially separated fluid conductive materials 240 are deposited in the channel 230, preferably by inkjet deposition means, the first fluid conductive material 240 being deposited at both the extreme left in FIG. 5c and also at the extreme right in FIG. 5c. A second fluid conductive material 250 is subsequently deposited in FIG. 5d in between the first two fluid conductive materials 240. In this example, the second fluid conductive material is electrically separated from the first conductive materials, due to surfactants that accumulate at the interface between the conductive materials. For example, after deposition of the first fluid conductive material 240 in FIG. 5c, a ‘self-aligned’ insulator 260 forms spontaneously over the free surface of the first fluid conductive material due to incorporation in the first fluid conductive material of surfactant species that diffuse to the interface, thereby preventing electrical contact to the subsequently deposited conductive material 250. The term ‘self aligned’ refers to the fact that such surfactants diffuse only to the free surface (fluid to air surface) of the deposited fluid, as is well known by those skilled in fluid surfactant chemistry, and is therefore aligned directly to this surface. This so-called spontaneous or ‘self-aligned’ insulator 260 is preferably formed just after deposition of the first fluid conductive material 240, for example by inkjet means, by including a polymeric surfactant in the first fluid conductive material 240, which surfactant moves by diffusion to the surface of the first fluid conductive material 240. Such a polymeric surfactant may comprise, for example, a urethane, fatty acid, silicone, styrene, or accrolate surfactant, which diffuses to the surface of the first fluid conductive material 240 to form insulator 260. Such polymeric surfactants are well known in the inkjet art. Alternatively, insulator 260 can be formed after deposition of a fluid conductive material and after the first fluid conductive material 240 is dried and/or annealed to become a conductive material, by selective atomic layer chemical vapor deposition of an insulator on the conductive materials or by physical or chemical deposition of an insulator followed by etch back, as is well known in the art of thin film semiconductor processing.

FIG. 5a illustrates in cross-section an ablative film 125 having a single ablative layer 170, an semiconductor active material layer 140, and a substrate 160 as in FIG. 4a, which layers are to be subjected to an alternative process for forming a transistor having source, drain, and gate connections.

FIG. 5b illustrates in cross-section the ablative film 125 of FIG. 5a after formation by laser radiation of a single channel (single ablated region) 230 extending down to the semiconductor active material layer 130.

FIG. 5c illustrates in cross-section the ablative film 125 of FIG. 5b after conductive materials 240 have been deposited, for example by inkjet printing, on the right and left portions of the single ablated channel 230. The conductive material 240 in FIG. 5c has been provided by first depositing a fluid conductive material 240, for example by inkjet printing, the fluid conductive material 240 containing a polymeric surfactant. The surfactant containing source-drain fluid material is first deposited on the right and left portions of the ablated channel 230 and is dried and/or annealed to form source-drain conductive material 240 on the right and left portions of the ablated channel. The polymeric surfactants accumulate on the deposited fluid conductive material surfaces where they act to insulate these conductive materials from subsequent deposition of a second fluid conductive material 250 (FIG. 5d) in a self-aligned manner. As further shown in FIG. 5c, the second conductive material 250 (FIG. 5d) is subsequently deposited to form a gate material 250 insulated from the source-drain conductive materials 240 on the right and left portions of the ablated channel 230, for example by the surfactants on their surfaces, as can be appreciated by one skilled in semiconductor device fabrication. The thickness of the surfactant layer, typically 10-100 nm, which insulates the source-drain conductive materials 240 on the right and left portions of the ablated channel 230 from the subsequently deposited gate conductive material 250, is much smaller than the spacing between the source and drain conductive materials 240 and the gate conductive material 250 provided by the device of FIG. 4a-d, which spacing is limited by the resolution of laser patterning, typically 1-2 microns. The small spacing is advantageous to the performance of the transistors, as is well know in the art of semiconductor fabrication.

FIG. 5d illustrates in cross-section the ablative film 125 of FIG. 5b after the single ablated channel (single ablated region) 230 has been filled with a conductive material of a first type 240 (containing surfactants) and of a second type 250. The second conductive material 250 subsequently deposited forms a gate material insulated from the source-drain conductive materials 240 on the right and left portions of the ablated channel 230 by the surfactants present on their surfaces, as can be appreciated by one skilled in semiconductor device fabrication. The combination of the two types of conductive materials 240 and 250 provide source, drain, and gate connections for the transistors so formed. The thickness of the surfactant layer 260 which insulates the source-drain conductive material 240 on the right and left portions of the ablated channel 230 from the subsequently deposited gate conductive material 260 is much smaller than the spacing between the source-drain conductive material 240 on the right and left portions of the ablated channel 230 from the subsequently deposited gate conductive material 250 for the device of FIG. 4a-d.

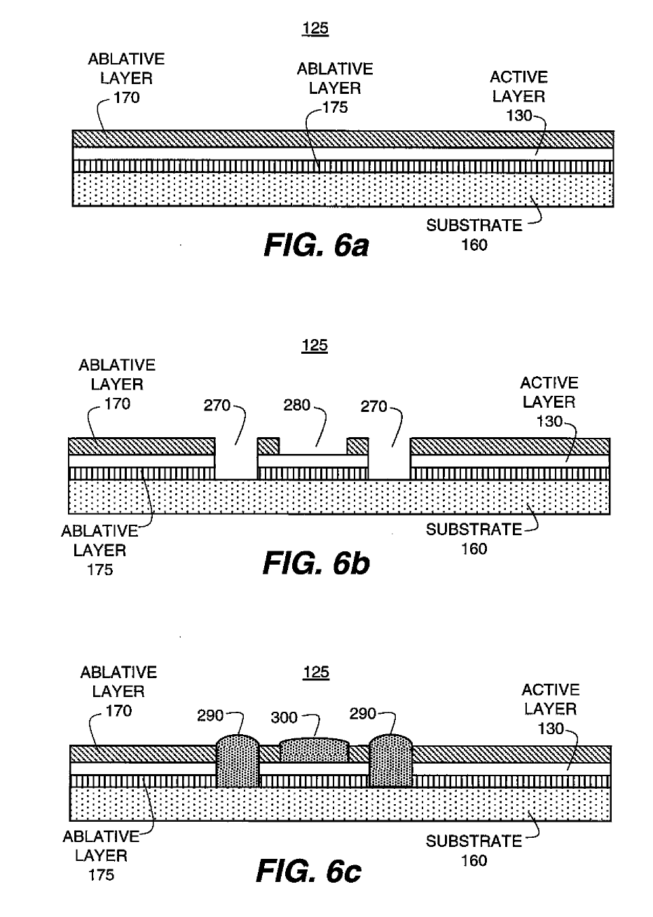

The embodiment depicted in FIGS. 6a-6c differs from the previous embodiments in that there are two ablative layers, 170 and 175. Ablative radiation can be adjusted in power and wavelength to ablate either layer or both layers, thereby providing the ability to ablate to multiple ablation depths. The single active layer 130 is sandwiched between the ablative layers 170 and 175.

The ablative channels 270 and 280 are formed using two different power and or wavelength levels, as is well known in the art of laser ablation. A single fluid conductive material type is deposited in each of the three ablated channels to form the source and drain conductive materials and the gate conductive material.

Referring to FIG. 6a, there is illustrated in cross-section an ablative film 125 comprising two ablative layers 170 and 175, lying under and over, respectively, an active layer 130, and a substrate 160 which layers are to be subjected to an alternative process for forming a transistor having source, drain, and gate connections.

FIG. 6b illustrates in cross-section the ablative film 125 of FIG. 6a after formation, by laser radiation, of three ablated channel regions (two deeply ablated regions 270, left and right in FIG. 6b, and one shallowly ablated region 280, center of FIG. 6b). The deeply ablated regions 270 extend down to the substrate 160 while the shallow ablated region 280 extends only to the active material 160. Advantageously, the active material 130 in the shallow ablated region 280 is not damaged since it is preferably chosen to be of the type that is typically processed at high temperatures.

FIG. 6c illustrates in cross-section the ablative film 125 of FIG. 6b after the ablated channels 270 and 280 have all been filled with a conductive material 290. The conductive materials in FIG. 6c have been provided by deposition of fluid conductive materials, for example by inkjet printing, followed by annealing or drying. In FIG. 6c, the fluid conductive materials are deposited and annealed to form source-drain conductive materials on the right and left ablated channels 270 spaced apart from a gate material located 300 between the source and drain materials 290. Advantageously, the fluids deposited in the outer channels (source-drain regions) 270 are not necessarily required to differ in their composition from the fluid deposited in the central channel (gate region) 280 in order that the materials in the outer channels can remove or degrade the insulator on the surface of the active material. This is because any dielectric insulator on the surfaces of the active materials in the active layer has already been removed at the ends of the active layer (FIG. 6b) during ablation of the ablative layer 175, underlying the active layer 130. In this example, the spacing between the source and gate (equivalently between the drain and gate) is determined by the resolution of the laser ablation process, typically 1 micron.

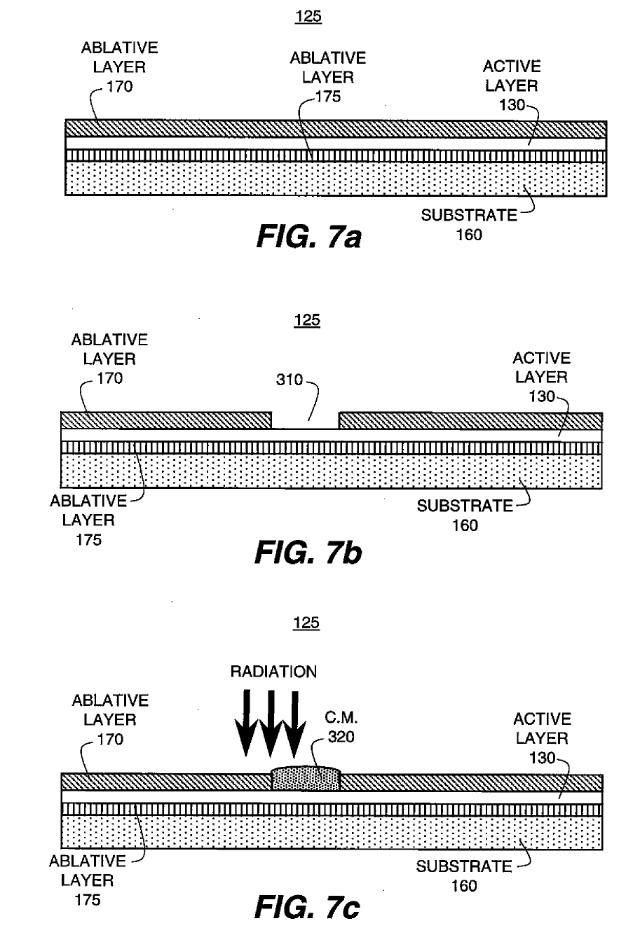

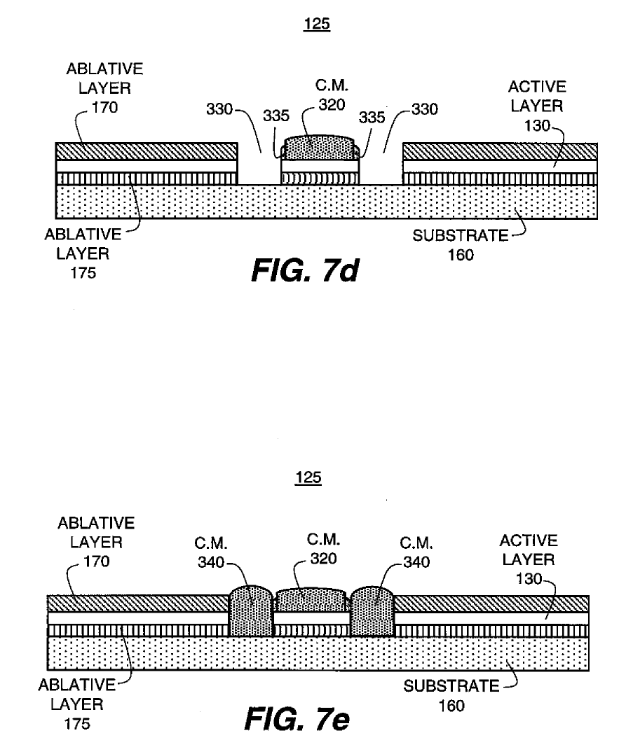

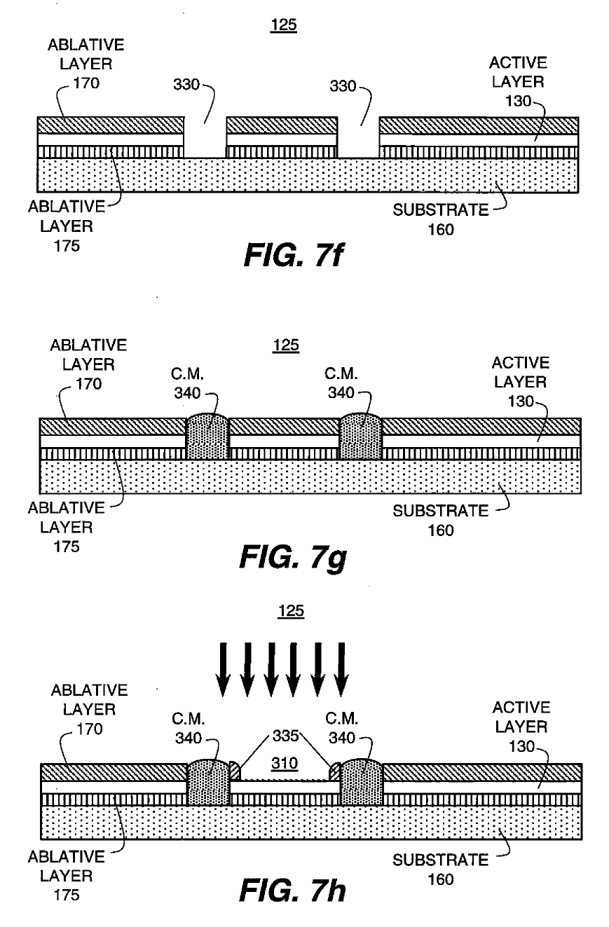

In general, FIGS. 7a-7e differ from the previous embodiment of FIG. 6a-6c in that the three channels (ablative regions) are formed sequentially rather than simultaneously, the central (gate) channel being filled with conductive material prior to the ablation of the outer (source-drain) channels. This allows formation of a “thermally self-aligned” dielectric on either side of the central conductive material as will be described, because the thermal mass of the conductive material prevents removal of the ablative adjacent the central (gate) conductive material during formation of the outer channels. The conductive material in FIG. 7c has been provided by deposition of a fluid conductive material, for example by inkjet printing, in the channel depicted in FIG. 7b, followed by annealing.

More specifically, FIG. 7a illustrates in cross-section the ablative film 125 having two ablative layers 170 and 175, lying under and over, respectively, an active layer 130, and a substrate 160. The layers 130, 170 and 175 are to be subjected to an alternative process for forming a transistor having source, drain, and gate electrical connections.

FIG. 7b illustrates in cross-section the ablative film 125 of FIG. 7a after formation, by laser radiation, of a single ablated channel 310. The ablated region extends down to the active material 130. Advantageously, the active material 130 is not damaged since it is of the type that is typically process at high temperatures.

FIG. 7c illustrates in cross-section the ablative film 125 of FIG. 7b after the ablated channel 310 has been filled with a conductive material 320. The conductive material 320 in FIG. 7c may be provided by first depositing a fluid conductive material 320, for example by inkjet printing, followed by drying and/or annealing. The arrows in FIG. 7c indicate the extent of laser radiation that forms the ablative channels described in FIG. 7d; the laser radiation source may extend over the central conductive material 320, since generally conductive materials reflect radiation.

FIG. 7d illustrates in cross-section the ablative film 125 of FIG. 7c after two additional ablated channels 330 have been formed. The edges of the additional ablated channels 330 are separated from the central conductive material 320 even though the laser radiation source extends over the central conductive material 320. This separation is said to be “thermally self-aligned” on either side of the central conductive material 320 because the separation is not dependent on the exact location of the laser radiation so long as the radiation extends over the central conductive material 320, as shown in FIG. 7c. This is because the thermal mass of the central conductive material 320 prevents removal of a portion (FIG. 7d, self-aligned sidewall spacer 335) of the second ablative material 175 adjacent the conductive material 320 in the central channel 310 and because the laser radiation is in part reflected from the central conductive material 320. Thus the material separating the gate and source-drain conductive materials is the same material as the top ablative layer 170. There is no need to have two fluid conductive material types in this embodiment because the ends of the active material will have been stripped of any gate dielectric during formation of the outer (source-drain) channels and no insulator is therefore present on the ends of the active material. Thus advantageously in this embodiment, the active material 130 is broken at each side of the additional (outer) two ablated channels 330 due to ablation of the ablative layer 175 nearest the substrate 160, so as to expose a fresh surface of the active material not covered by a dielectric insulator, thereby affording subsequent ohmic electrical contact to its ends without the need for etchant chemicals to be included in the outer fluid conductive material (FIG. 7e).

FIG. 7e illustrates in cross-section the ablative film 125 of FIG. 7b after the additional ablated channels 330 have been filled with a conductive material 340. The conductive materials 340 in FIG. 7d have been preferably provided by first depositing a fluid conductive material 340, for example by inkjet printing and then drying or annealing the fluid conductive material 340 to form conductive material 340. In contrast to the conductive materials deposited in FIG. 4c, which must differ in their composition in order that the materials in the outer channels can penetrate the insulator surrounding the active material in the active layer, the fluids deposited need not perform that function and may be identical in accordance with this embodiment.

FIGS. 7f-7i illustrate an alternative process similar to the process described in association with FIG. 7a-7e, except that the order of providing the central ablative channel and the additional (outer or side) ablative channels is reversed. FIG. 7h shows the lateral extent of the laser radiation used to ablate the central channel 310; the radiation overlaps the outer channels 330 which have been filled with conductive material 340. Otherwise the processes are essential the same. This process is advantageous in that some annealing may be performed after the step shown in FIG. 7g to allow ohmic contact to form between the active material ends and the conductive material in the additional side channels prior to formation of the gate conductive material. Also in accordance with this embodiment, the location of the central ablated channel 310 is more easily determined after the conductive materials 340 have been formed in the side channels.

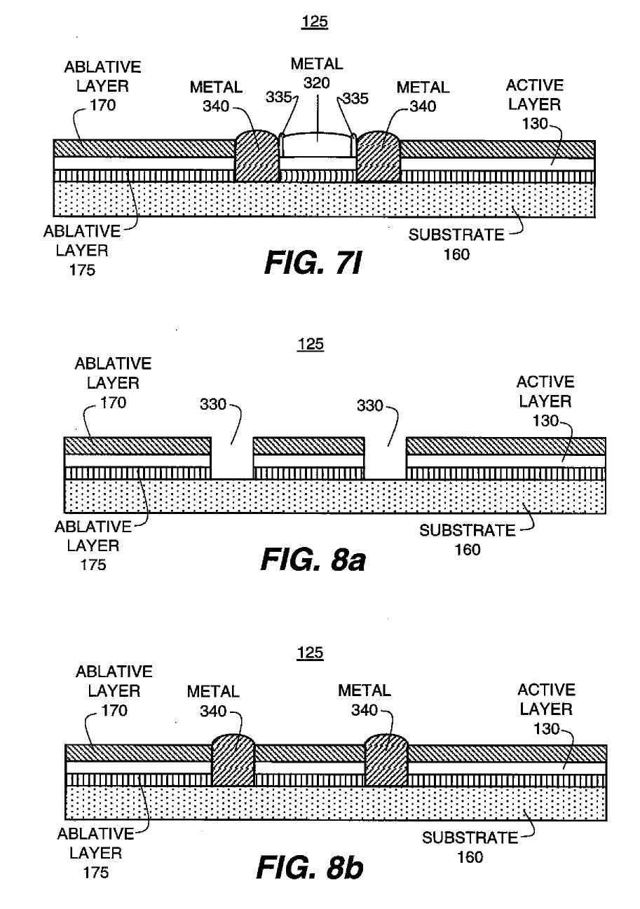

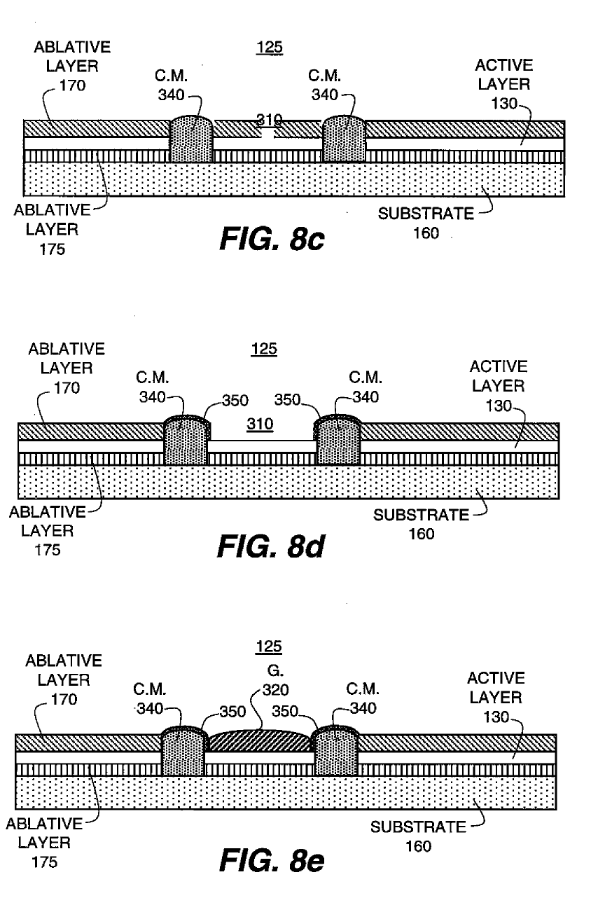

In general, FIGS. 8a-8e differs from the previous embodiment of FIGS. 7f-7h in that the central channel 310 is formed sufficiently wide and with sufficient radiative power to remove the “thermally self-aligned” ablative later entirely between the outer conductive materials 340 and thereby expose the conductive materials at either edge. A selectively deposited insulative coating 350 is subsequently formed before deposition of the gate conductive material 320 so as to electrically insulate the subsequently deposited gate conductive material from the source and drain conductive material 340. As in the previous embodiments, the active layer 130 in FIG. 7a-c is preferably envisioned to be surrounded, at least on the top and the bottom, with dielectric layers (insulator, such as silicon oxide) which act as all or part of a gate dielectric. This embodiment allows self-alignment of source/drain to gate in the sense that the alignment is determined by the thickness of the selectively deposited insulative coating 350.

FIGS. 8a and 8b illustrate the initial steps of a process for providing transistors which begin identically to that illustrated in FIG. 7a and 7b.

FIG. 8c shows deposition of conductive materials 340, analogous to that illustrated in FIG. 7c, except the ablated central channel 310 extends laterally to the conductive materials on both sides. Thus the central channel 310 is formed sufficiently wide and with sufficient radiative power to remove the ablative layer 170 entirely between the outer conductive materials 340 and thereby expose the conductive materials 340 at either edge. This is advantageous for alignment of the central channel 310, which is now symmetrically aligned to the conductive materials 340 on both sides; the laser radiation extending substantially over one or both of the conductive materials 340 to either side as illustrated in FIG. 7h.

FIG. 8d shows selective deposition of an insulative material 350 on the conductive materials 340, for example by vapor exposure to materials that adhere only to metals. Alternatively, the deposited fluid conductive material 340 deposited in FIG. 8c may contain polymeric surfactants that diffuse to their free surfaces after they are deposited and remain on these surfaces after the fluid conductive material 340 has been dried and/or annealed as in FIG. 5c.

FIG. 8e illustrates in cross-section the device of FIG. 8d after the central ablated channel 310 has been filled with a conductive material 320 to form the transistor gate.

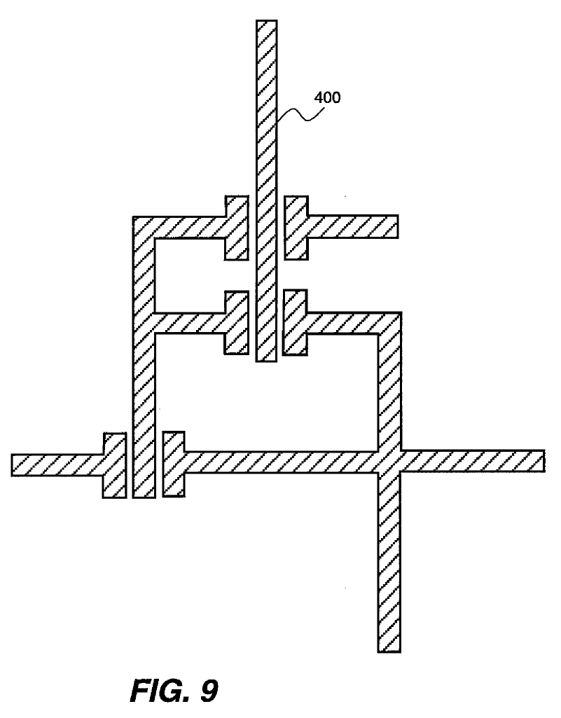

FIG. 9 shows a schematic top view of circuitry created by the embodiments described above, the dark lines representing electrical conductive interconnects 400, such as conductive materials deposited in ablated channels or pre-patterned metal films or both, illustrating the use of the present invention in building up systems comprising a plurality of the transistor structures described in detail. The present invention contemplates the use of large-area ablative films (multiple square meters) processed to contain thousands or millions of such transistor circuits.

The invention has been described with reference to a preferred embodiment. However, it will be appreciated that variations and modifications can be effected by a person of ordinary skill in the art without departing from the scope of the invention.

### Parts List

5 ablative film
10 substrate
20 energy absorbing layer
30 four layers
40 channel
50 altered absorbing layer
60 electrically conductive material
90 active element
110 electrical connection
120 connecting material
125 ablative film
130 active layer
140 active material
150 insulator
160 substrate
170 ablative layer
175 ablative layer
180 source region
190 drain region
200 gate region
210 channels (ablative region)
220 segments
221 recess portions
222 first electrical conductive material
223 dielectric material
224 second conductive material
230 contiguous channel (ablative region)
240 spatially separated fluid conductive material
250 second fluid conductive material
260 spontaneous or ‘self aligned” insulator
270 ablated channel regions
280 ablated channel regions
290 conductive material (source/drain)
300 conductive material (gate)
310 single ablative channel
320 conductive material (gate)
330 additional ablative channel
335 “self-aligned” sidewall spacer
340 conductive material (source/drain)
350 coating (insulative material)
400 electrical conductive interconnects

1. An ablative film arranged in a stack, the ablative film comprising:
a flexible substrate disposed in the stack;
an active layer, disposed in the stack, including at least a semiconductor material; and
at least one ablative layer, disposed in the stack over the active layer, that is removable by image wise exposure to radiation from the top side of the stack.

2. An ablative film in accordance with claim 1 in which the semiconductor material is surrounded entirely or partially by a dielectric insulator.

3. The ablative film as in claim 1 wherein the substrate is rigid.

4. The ablative film as in claim 2 wherein the substrate is rigid.

5. The ablative film as in claim 1 wherein the active layer is patterned laterally.

6. The ablative film as in claim 2 wherein the active layer is patterned laterally.

7. The ablative film as in claim 2, wherein the ablative layer is absorptive in wavelength ranges from approximately 800 to 1200 nm.

8. The ablative film as in claim 2 wherein the ablative layer has an absorption coefficient substantially in the range of greater than or equal to 200,000 m-1.

9. The ablative film as in claim 1 wherein the ratio of absorption coefficients of the ablative layer and the active layer that is greater than 5.

10. The ablative film as in claim 2 wherein the ratio of absorption coefficients of the ablative layer and the active layer that is greater than 5.

11. The ablative film as in claim 1 further comprising lateral dimensions of the ablative film that exceed 100 cm in at least one direction.

12. The ablative film as in claim 2 further comprising lateral dimensions of the ablative film that exceed 100 cm in at least one direction.

13. The ablative film as in claim 1 wherein the semi-conductive material comprises a plurality of pieces shaped in the form of thin flakes.

14. The ablative film as in claim 2 wherein the semi-conductive material comprises a plurality of pieces shaped in the form of thin flakes.

15. The ablative film as in claim 1 wherein the semi-conductive material comprises a plurality of pieces cylindrically shaped having a diameter less than 0.1 micron and a length greater than 5 microns.

16. The ablative film as in claim 2 wherein the semi-conductive material comprises a plurality of pieces cylindrically shaped having a diameter less than 0.1 micron and a length greater than 5 microns.

17. The ablative film as in claim 15, wherein the semiconductor material is substantially angularly aligned.

18. The ablative film as in claim 15 in which the density of the semi-conductive material pieces is sufficiently small so that no conductive path between them is formed over distances greater than 10 times their largest dimension.

19. The ablative film as in claim 1 wherein the stack is arranged in the order of substrate, ablative layer, active layer and a second ablative layer.

20. The ablative film as in claim 2 wherein the stack is arranged in the order of substrate, ablative layer, active layer and a second ablative layer.

21. A method for creating a transistor on an ablative film, the method comprising the steps of:
(a) providing at least one active layer having a semi-conductor surrounded entirely or partially by an insulator;
(b) providing at least one ablative layer in contact with the active layer;
(c) ablating the ablative layer at one or more locations which respectively creates one or more recess portions in the ablative layer; and
(d) providing an electrical conductor in each of the one or more recess portions.

22. The method as in claim 21 in which the electrical conductor is provided by depositing a fluid conductive material.

23. The method of claim 22, wherein the fluid conductive material includes an etchant means to provide ohmic contact to the semi-conductor through the insulator.

24. The method of claim 21, wherein the electrical conductor connects a plurality of transistors so formed.

25. A method for creating a transistor from an ablative film, the method comprising the steps of (a) ablating a portion of the ablative film; (b) providing liquid deposition by jetting, and (c) annealing the liquid deposition.

26. A method for forming a transistor from an ablative layer and an active layer, the method comprising the steps of providing a plurality of separate ablated channels ablated to a common depth in the ablative layer for forming source and drain regions and at least one channel terminating on an active layer in the gate region

27. A method for forming a transistor from an ablative layer and an active layer, the method comprising the steps of: terminating the channels on the active layer contiguously in the regions comprising the gate, drain, and source.

28. The method of claim 27 further comprising the step of providing a fluid conductive material having surfactants that form an insulator on at least a portion of its surface and placing a gate contact between at least a portion of the surfactant insulated surfaces.

29. A method for forming a transistor, the method comprising the steps of:
(a) providing a layered stack in the order of substrate, ablative layer, active layer and a second ablative layer;
(b) disposing a source and drain in both ablative layers and the active layer;
(c) irradiating the source and drain that causes a sidewall spacer to form on both the source and drain; and
(d) forming a gate between the sidewall spacers.

30. The method of claim 29 further comprising the step of ablating one portion of the first ablative layer at a first power level and two portions of the first and second ablative layer at a second power level, higher than the first power level, so that the portion ablated at the second power level exposes the ends of the active layer, and providing a contact in contact with each exposed end of the active layer.

31. The method of claim 29, wherein at least one channel is ablated to a depth so as to terminate below the active layer at least in the gate region so as to provide a back-gate upon deposition of the liquid conductive material

32. The method of claim 29 further comprising providing a plurality of ablated channels ablated to selective depths, the source and drain channels terminating below the active layer and the gate channel terminating on the active layer in the gate region so as to provide source and drain connections upon deposition of a liquid conductive material.

33. The method of claim 29, wherein the first channels are filled with a conductive material prior to the ablation of the second channel and the ablative radiation used to form the second channel extends over the both conductive materials so as to self-align the spacing between first and second channels.

34. The method of claim 29, wherein the first channel is filled with a conductive material prior to the ablation of the second channels and the ablative radiation used to form the second channels extends over the conductive material so as to self-align the spacing between first and second channels.

35. A method for creating a transistor, the method comprising the steps of:
(a) providing at least one active layer having a conductor;
(b) providing at least one ablative layer in contact with the active layer;
(c) ablating the ablative layer at two locations which respectfully creates two recess portions in the ablative layer;
(d) providing a contact in each of the two recess portions;
(e) ablating the ablative layer a subsequent time between the two contacts;
(f) placing a dielectric on at least a portion of the contacts and on the active layer between the two contacts; and
(g) placing a metal material on the dielectric between the contacts for forming a gate structure.

36. A method for creating a transistor, the method comprising the steps of:
(a) providing at least one active layer having a conductor;
(b) providing at least one ablative layer in contact with the active layer;
(c) ablating the ablative layer at two locations which respectively creates two recess portions in the ablative layer;
(d) providing a contact in each of the two recess portions;
(e) ablating the ablative layer a subsequent time between the two contacts;
(f) placing a dielectric on at least a portion of the contacts and on the active layer between the two contacts; and
(g) placing a metal material on the dielectric between the contacts for forming a gate structure.

37. A method for creating transistor circuits, the method comprising the steps of:
(a) providing a substrate;
(b) providing at least one ablative layer that is removable by exposure to radiation;
(c) providing an active layer including a semiconductor material surrounded at least partially by a dielectric; and
(d) providing conductive materials, deposited in a plurality of ablated channels, electrically connecting a plurality of the transistor structures to form transistor circuits.
